(19) United States
(12) Patent Application Publication
(10) Pub. No.: US 2014/0352605 A1
(43) Pub. Date: Dec. 4, 2014

(54) METHOD FOR MAKING BARIUM-DOPED CRUCIBLE AND CRUCIBLE MADE THEREBY

(71) Applicant: Heraeus Shin-Etsu America, Inc., Camas, WA (US)

(72) Inventors: Michael R. Fallows, Battle Ground, WA (US); Jeffrey S. Bailey, JR., Troutdale, OR (US); Katsuhiko Kemmochi, Vancouver, WA (US)

(73) Assignee: Heraeus Shin-Etsu America, Inc., Camas, WA (US)

(21) Appl. No.: 14/012,795

(22) Filed: Aug. 28, 2013

Related U.S. Application Data
(60) Provisional application No. 61/829,890, filed on May 31, 2013.

(51) Int. Cl. C30B 15/10; C30B 15/00

(52) U.S. Cl. CPC C30B 15/10; C30B 15/002
USPC 117/33; 117/208; 117/13; 427/230

(57) ABSTRACT

Making a barium-doped silica crucible includes forming a crucible by introducing into a rotating crucible mold bulk silica grains to form a bulky wall. After heating the interior of the mold to fuse the bulk silica grains, an inner silica grain, doped with barium, is introduced into the crucible. Residual heat or additional heat at least partially melts the inner silica grain, allowing the barium-doped silica layer to fuse to the wall of the crucible to form a glossy inner layer. Next, at least a part of the barium-doped silica layer is roughened. Also described are the crucible made thereby as well as silicon ingots made using the crucibles as described herein.

### FIELD OF THE INVENTION

This disclosure is directed to crucibles, and, more particularly, to crucibles for use in silicon production.

### BACKGROUND

The Czochralski (CZ) process is well-known in the art for production of ingots of single crystalline silicon, from which silicon wafers are made for use in the semiconductor and solar industries.

In the CZ process, metallic silicon is charged in a silica glass crucible housed within a susceptor. The charge is then heated by a heater surrounding the susceptor to melt the charged silicon. A single silicon crystal is pulled from the silicon melt at or near the melting temperature of silicon.

To reduce costs, a current trend in solar cell production is to increase throughput. One method of increasing throughput is multiple-pulling, where several batches of the CZ process are repeated in the same crucible, without cooling down the crucible between batches. Another example of increasing throughput is by pulling a continuous ingot of silicon where additional silicon is added to the crucible and melted as the ingot is being pulled. In either case, a single crucible may be used for a long period of time, such as hundreds of hours.

The working life of a silica crucible involved in the CZ process is finite. At typical operating temperatures, the inner surface of the silica crucible reacts with the silicon melt. These reactions are believed to shorten the life of a crucible in a manner that is not fully understood. One method of extending the life of a crucible is to use a crystallization enhancer. Crystallized silica is believed to react less aggressively with the silicon melt than non-crystallized silica. Crystallized silica also produces a smoother crucible surface-melt interface than does non-crystallized silica. The crystallization enhancer is sometimes referred to as a devitrification promoter or mineralizer, because it helps convert the inner layer of silica glass of the crucible to crystalline silica during a CZ run.

Some crucibles use a barium-containing coating as a devitrification promoter, such as disclosed in U.S. Pat. Nos. 5,976,247 and 5,980,629, both by Hansen et al. Such a devitrification promoter is taught to prevent particulate generation at the silica-melt interface, thus resulting in a longer life for the crucible. Barium carbonate (BaCO₃) is disclosed as a preferred coating material, although other alkaline-earth metal compounds are also disclosed. The coating is performed as a post-treatment of a finished crucible by applying a solution of barium-containing chemicals. A more economical method was proposed in U.S. Pat. Nos. 6,651,663 and 7,427,327, both by Kemmochi et al., which are incorporated by reference herein. These references teach doping elemental barium to the inner layer of the crucible during its formation, eliminating post-processing and reducing the amount of elemental barium used in the process.

Making the Ba-doped crucible normally requires fine design tunings depending on the CZ process conditions. Design parameters include concentration of Ba in the doped layer, layer thickness, and bubble content in the doped layer and substrate layer, for example. CZ process conditions are not only specified by the temperature and heating time. An actual temperature of the silicon charge and crucible are influenced by the size and shape of the silicon charge and how the charge is melted over time. The amount and speed of crystallization is supposed to depend on whether the crucible contacts with the silicon melt. In practice, there are many types of polysilicon raw material, such as chunk silicon, granular silicon, and recycled tail and shoulders of pulled ingots mixed together in the CZ process. The actual temperature and crystallization can fluctuate depending on any or all of these variables. It is therefore difficult to efficiently produce Ba-doped crucibles using prior art methods.

Embodiments of the invention address these and other limitations of the prior art.

### SUMMARY OF THE INVENTION

Aspects of the invention include a silica crucible with a first portion having substantially straight walls and a second body portion having substantially curved walls. At least a portion of the inner surface of the curved walls includes a barium-doped layer of silica. At least a portion of the barium-doped layer of silica is roughened to a surface roughness greater than approximately 0.07 micrometers and less than approximately 10 micrometers.

Not all of the barium-doped layer needs to be roughened; some of the barium-doped layer may remain smooth as the virgin surface of the fused crucible. The bottom surface of the crucible may remain smooth.

Not all of the crucible needs to be covered with the barium-doped layer of silica. Specifically, an upper sidewall portion of the crucible may include areas where there is pure silica substrate.

The barium-doped layer of silica is thicker than approximately 0.2 mm and thinner than approximately 0.8 mm, and is optimum at 0.5 mm.

The barium-doped layer of silica may have a barium concentration between approximately 30-300 ppm.

Methods of making the barium-doped silica crucible, as well as methods of producing silicon ingots and the ingots produced thereby are also claimed.

### BRIEF DESCRIPTION OF THE DRAWINGS

FIG. 1 is diagram illustrating a silicon melt in a crucible including at least a partially roughened Barium-doped layer according to embodiments of the invention.

FIG. 2 is diagram illustrating the crucible of FIG. 1 as a silicon ingot is being pulled therefrom.

FIG. 3 is a flow diagram illustrating an example method of forming a crucible according to embodiments of the invention.

FIG. 4 is an illustration of a magnified inner surface of a test crucible after a Vacuum Bake Test according to embodiments of the invention, showing relatively homogenous devitrification of the crucible.

FIG. 5 is an illustration of a magnified inner surface of another test crucible according to the prior art after a Vacuum Bake Test, showing non-homogenous patchy devitrification of the regularly glossy surface of the crucible.

FIG. 6 is a diagram of a piece of crucible cut at a corner area and illustrating sections of the bottom area, corner area, and lower wall after a Vacuum Bake Test.

FIG. 7 is a diagram of another piece of crucible cut at a corner area and illustrating sections of the bottom area, corner area, and lower wall after a Vacuum Bake Test illustrating bubble growth under the crystallized layer at the corner area.

### DETAILED DESCRIPTION

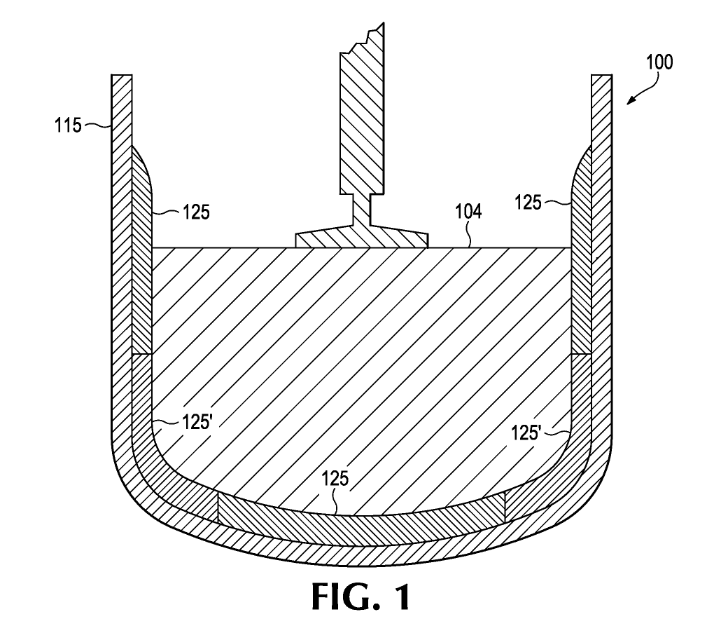

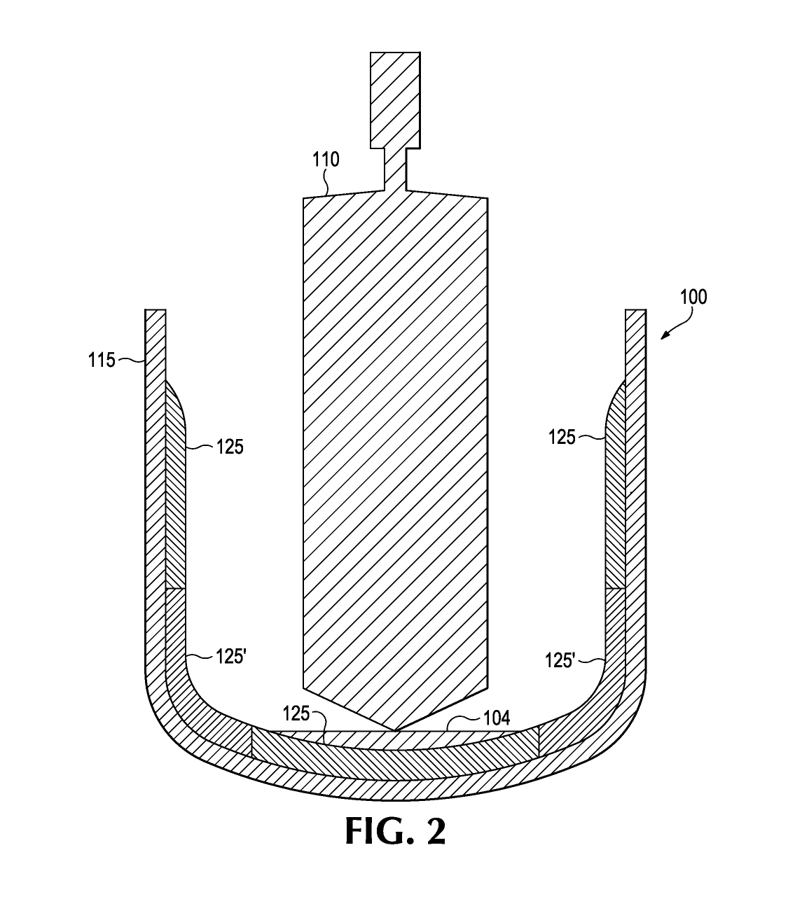

FIG. 1 is a diagram illustrating a silica crucible 100 according to embodiments of the invention. The crucible 100 of FIG. 1 is holding melted silicon 104 as it is preparing to be pulled into a silicon ingot in a CZ process, and FIG. 2 illustrates a silicon ingot 110 while it is being pulled from the crucible 100.

The crucible 100 includes three general zones—a side wall, a corner wall, and a bottom wall. Sometimes these areas of a crucible are referred to as cylindrical, toroidal, and spherical, respectively, which roughly correspond to three-dimensional shapes of sections of the crucible in those zones. The sidewall is sometimes described as including upper and lower portions.

Embodiments of the invention include a barium-doped inner layer 125 in portions of the crucible 100. The barium-doped inner layer 125 differs from previous layers in that the inner layer is roughened to a textured surface as illustrated by 125′. The roughened portion is not limited to what is illustrated in FIG. 1, but instead less or more of the barium-doped inner layer 125 may be roughened to form roughened layer 125′ depending on implementation. In other embodiments portions of the crucible 100 outside beyond the barium-doped inner layer 125 may also be roughened.

Roughness of a surface is a measure of its texture, and may be measured or referred to in a number of forms. A roughness parameter, Ra, is generally calculated by averaging absolute values of distance measurements between the textured surface and its ideal surface. The roughness parameter Ra is usually expressed in units of height, such as an Ra of 2 um (micrometers). A higher roughness parameter indicates a surface that is more rough.

Roughening of the barium-doped inner layer 125 promotes a homogeneous crystallization of the crucible when the crucible is heated. Using a roughened barium-doped inner layer 125′, rather than a doped layer with a glazed, glossy surface, permits the crucible designer to minimize fine tunings to the variation of CZ process parameters. In other words, such a crucible is easier to manufacture and is also more robust in a wide variety of CZ operations, where numerous variations can be introduced even when manufacturing processes are well controlled.

Referring back to FIG. 2, as the silicon ingot 110 is pulled from the crucible 100 using the CZ process, the barium-doped inner layer 125, 125′ crystallizes, or devitrifies the inner layer of the crucible. This process extends the operating life of the crucible 100. As illustrated, in general, the upper side wall is mostly above the silicon melt 104, while, as illustrated in FIG. 1, the lower side wall contacts the silicon melt. The silicon melt 104 travels down within the crucible 100 during pulling of the silicon ingot 110. When the last silicon ingot 110, or the last portion of the silicon ingot 110 is being pulled, the surface of the silicon melt 104 travels down further into the corner wall of the crucible 100. The bottom portion of the crucible 100 generally stays under the silicon melt 104 while the silicon ingot 110 or ingots are being pulled. It is not necessary that the barium-doped inner layer 125 of FIGS. 1 and 2 cover the upper portion of the side walls of the crucible 100. These areas are typically not in contact with the silicon melt 104.

Referring back to FIGS. 1 and 2, the side wall of the crucible 100 includes areas of pure silica substrate 115, as well as areas having the barium-doped inner layer 125. In general, the pure silica substrate 115 is formed of multi-layers having a translucent layer as well as a transparent layer, both made of essentially pure silica. The barium-doped inner layer 125 generally includes fused, doped silica, and is normally transparent.

In one particular exemplary illustrated embodiment, referring back to FIG. 1, a crucible 100 has an interior surface covered by a barium-doped inner layer 125. The thickness of the doped inner layer 125 at the lower side wall, corner wall, and bottom wall is 0.4 mm, 0.5 mm, and 0.4 mm, respectively. The barium-doped inner layer 125′ was roughened by sand blasting the inner layer in the corner wall and lower side wall while rotating the mold. The portion of the barium-doped inner layer 125 covering the bottom wall was left glassy, although in other embodiments may also be roughened.

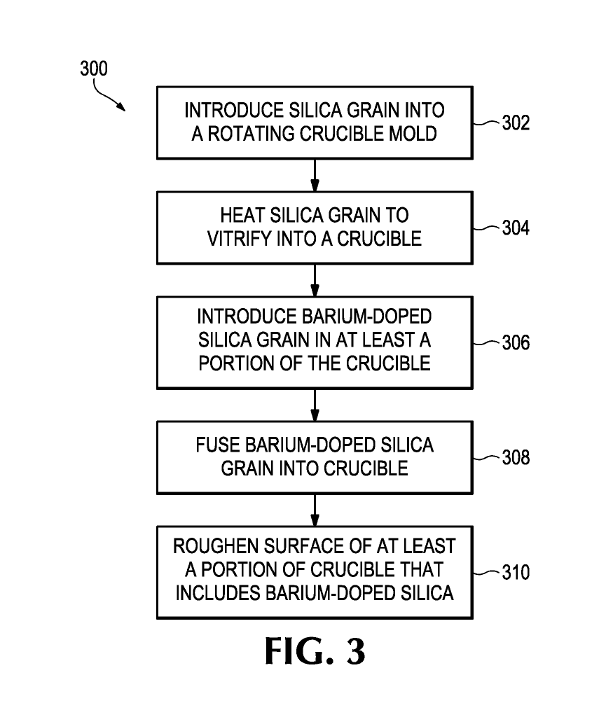

Methods of making the barium-doped inner layer of a crucible according to embodiments of the invention are now described with reference to FIG. 3.

FIG. 3 is a flow diagram illustrating an example method 300 of forming a crucible according to embodiments of the invention. In general, silica grain consisting essentially of quartz grain is introduced into a rotating crucible mold to form a bulky wall in an operation 302. After heating the interior of the mold to fuse the bulk silica grains in an operation 304, an inner silica grain, doped with barium, is introduced into the mold in an operation 306. As mentioned above, the doped layer thickness is generally thicker at the corners, which is due to the method used to make the doped layer. As the grains of the doped layer are introduced, centrifugal force of the spinning crucible as well as gravity work together to make the doped layer thicker at the corner. In the CZ process, the corner portion typically experiences the hottest heating conditions. In some embodiments the doped silica grain is not even directed to the upper side wall. Instead, in those embodiments, the upper side wall is a pure silica substrate.

The heat of the crucible mold while the doped layer is being introduced also at least partially melts the inner silica grain, allowing it to fuse to the wall in an operation 308 to form an inner layer having a glazed, glossy surface.

The doped silica grain used in operation 306 may be doped with elemental barium in a range of 30-300 ppm, and preferably 80-200 ppm, and even more preferably 100-150 ppm. After the doped inner layer is formed during operation 308, it has a thickness in the range of 0.2 mm-0.8 mm, and preferably 0.3 mm-0.5 mm. The illustrations of FIGS. 1-4 are not shown to scale, but rather are scaled to particularly point out where the doped inner layer may be placed in various embodiments.

After the doped inner layer has cooled, at least a portion of the surface of the doped inner layer is roughened in an operation 310.

Roughening of the doped inner layer may be effected in a number of ways, including using mechanical or chemical methods. For example, the surface of the doped inner layer may be roughened by blasting it with quartz sand, such as quartz sand propelled by pressurized air. Other methods of roughing include honing, lapping, or scratching. One particular method of scratching includes placing silica grains under a pad and then manually sanding the areas of the inner layer that are to be roughened. Lapping may be performed by lapping with a soft pad using quartz sand as the lapping media. The doped inner layer may also be mechanically knurled to produce a rough surface.

In other embodiments the doped inner layer may be roughened in a chemical process, such as frosting. For example, the doped inner layer may be subjected to hydrofluoric etching, and then rinsed with de-ionized water.

The roughening of the doped inner layer may occur while the crucible is still in the mold, or may be performed after the crucible has been extracted from its mold.

Notably, the entirety of the doped inner layer need not be roughened, but satisfactory results are achieved when even only a portion of the doped inner layer is roughened. For example, the doped inner layer covering the bottom wall need not necessarily be roughened. Nor is the roughing limited to only including the doped inner layer. In other words, portions of the crucible not covered by the doped inner layer may also be roughened and still produce good results.

Embodiments of the invention include a barium-doped layer of silica having a surface roughness, Ra, greater than 0.07 micrometers and less than 10 micrometers, and preferably greater than 0.15 micrometers and less than 5 micrometers.

Further, as mentioned above, the doped inner layer need not cover the entirety of the crucible. Specifically, the doped inner layer need not extend to the upper side wall, which will not contact the silicon melt during the CZ process.

Other steps in finishing the crucible may include cutting the crucible to its desired height, and then chamfering the inside and outside top edges to prevent or reduce chipping.

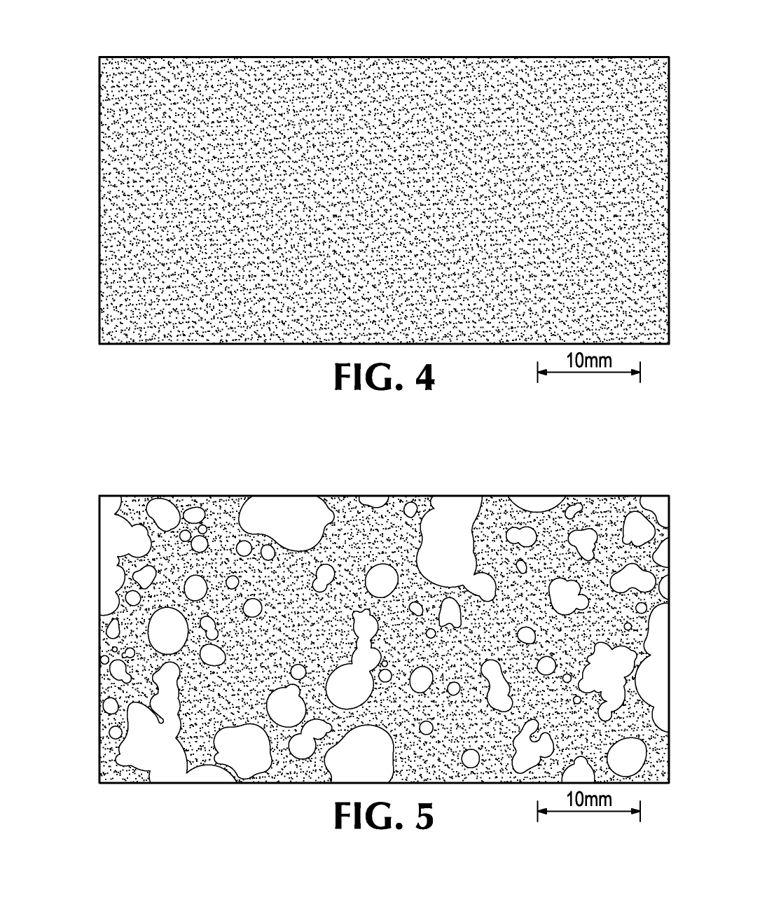

Testing of crucibles may be done using a technique known as a Vacuum Bake Test, typically performed at 1550° C. for approximately 2 hours in 1 mbar Argon gas environment. Results of the bake test suggest how a crucible crystallizes in the CZ process. Examples of tested crucibles are shown in FIGS. 4 and 5. FIG. 4 illustrates an inner surface of a coupon of a crucible made according to embodiments of the invention, i.e., having a roughened and doped inner layer. After the coupon was cooled, relatively uniform devitrification is present as shown in FIG. 4. In contrast, FIG. 5 illustrates an inner surface of a coupon of the same crucible as in FIG. 4, except the inner surface was not roughened, such as in conventional crucibles. Unlike the uniform devitrification illustrated in FIG. 4, FIG. 5 illustrates non-uniform devitrification that is patchy, splotchy, and relatively uneven.

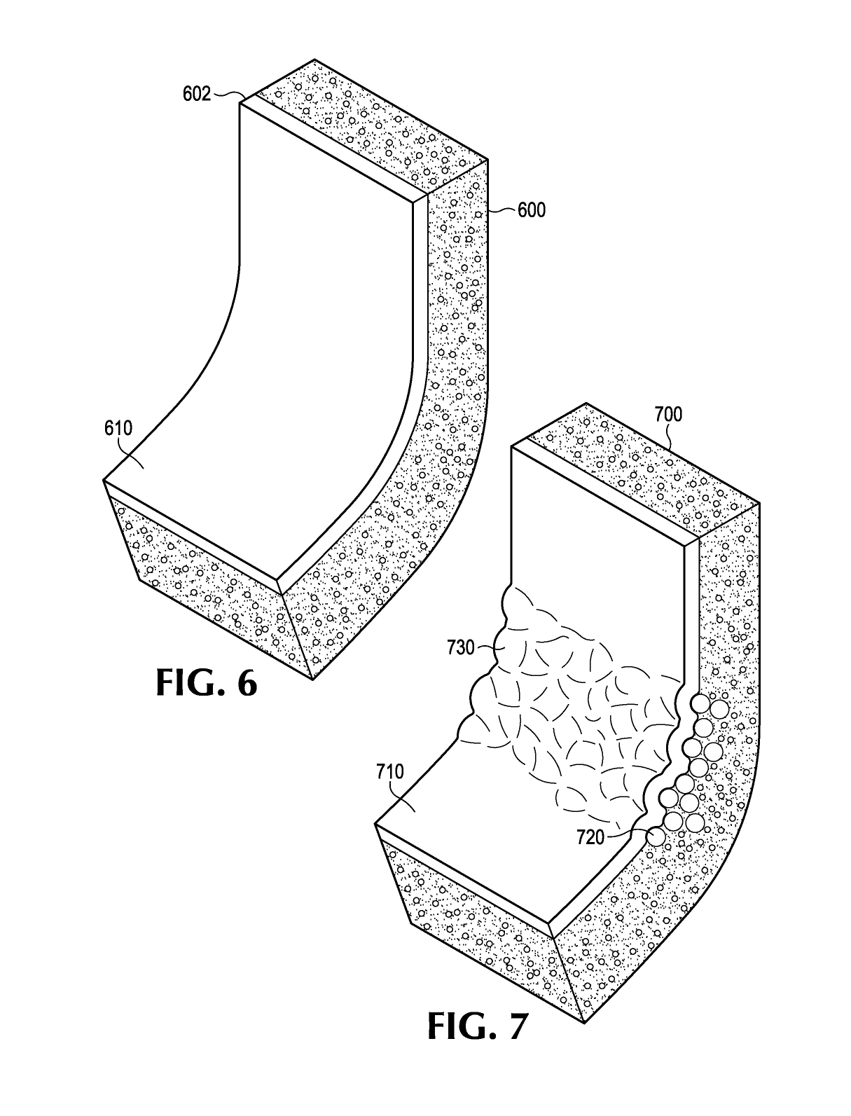

Examples of tested crucibles are also shown in FIGS. 6 and 7. A three-dimensional illustration of a test piece 600 taken from a corner area of a crucible is shown in FIG. 6. In FIG. 7, a thickness of a Ba-doped layer in a test crucible 700 was increased to 1.8 mm at the corner. The interior surface was left as glossy, without roughening as described above. The entire interior surface of the crucible was covered by a crystallized layer 710 but the surface at the corner showed bumps 730 covering grown bubbles 720 underneath. When a crucible having these bumps 720 is used for the CZ process, the bumped area 730 reacts with silicon melt and holes are created in the bumped layer 730. The silicon melt travels goes through the holes and penetrates between the crystallized layer and the crucible substrate. This is termed “Melt-Penetration”, as demonstrated in the U.S. Pat. No. 7,427,327. The melt penetration tends to terminate the CZ run before the completion.

Example crucibles according to embodiments of the invention were made and tested. Their parameters are listed in Table 1 and are described below. All of the crucibles have similar physical dimensions, e.g., 457 mm in diameter and 355 mm in height.

TABLE 1

| | | Thickness of Ba- | | Performance and |
|---|---|---|---|---|
| | | doped inner layer | Appearance | appearance of |
| Test | Roughness (Ra), in | (bottom/corner/lower | after Vacuum | crucible after CZ |
| Trial | micrometers | side), in mm | Bake Test | process |
| A | 2.2 micrometers | 0.4/0.5/0.4 | Uniform | 120 hour run |
| | on side wall and | | crystallized | successful. |
| | corner radius | | surface | Uniform |
| | | | | crystallization |
| B | 4.3 micrometers | 0.4/0.5/0.4 | Uniform | 120 hour run |
| | on side wall and | | crystallized | successful. |
| | corner radius | | surface | Uniform |
| | | | | crystallization |
| C | 2.2 micrometers | 0.2/0.3/0.2 | Uniform | 120 hour run |
| | on side wall and | | crystallized | successful. |
| | corner radius | | surface | Uniform |
| | | | | crystallization |
| D | 2.2 micrometers | 0.4/0.5/0.4 | Uniform | 120 hour run |
| | on whole inside | | crystallized | successful. |
| | | | surface | Uniform |
| | | | | crystallization |
| E | 0.2 micrometers | 0.4/0.5/0.4 | Uniform | 120 hour run |
| | on side wall and | | crystallized | successful. |
| | corner radius | | surface | Uniform |
| | | | | crystallization |
| F | <0.02 micrometers | 0.6/1.7/0.7 | Uniform | Terminated run at |
| | Glossy surface | | crystallized | 95 hours. |
| | | | surface | Melt-penetration |
| | | | | observed. |
| G | <0.02 micrometers | 0.4/0.5/0.4 | 80% surface | Terminated run at |
| | Glossy surface | | crystallized | 80 hours. |
| H | <0.02 micrometers | 0.2/0.3/0.2 | Patchy | 120 hour run |
| | Glossy surface | | devitrification | successful with |
| | | | Ca. 60% | many CZ process |
| | | | surface | changes. |

Tests A, B, C, D, and E are tests of embodiments of this invention. Test F is a comparative example of trial to eliminate patchy crystallization by increasing the thickness of the Ba-doped layer. This test F shows a “melt-penetration” problem because the doped layer was too thick which created the imperfections in the crucible as described above. The tests G and H are comparative examples of Ba-doped crucibles with known technologies, where the whole inner surface is glossy, and not roughened as in embodiments of the invention. As is illustrated in the table, the thickness of the barium-doped inner layer varied from 0.2 mm-0.5 mm depending on the particular crucible design. The thickness of the barium-doped inner layer also varied depending on its location within the crucible, as shown in Table 1.

In these tests illustrated in Table 1, the inner surface of the barium-doped inner layer was roughened by sand-blasting using quartz sand with different grain size. Surface roughness, expressed as Ra, was measured using a roughness tester having a 5 micrometer tip.

The thickness of the doped inner layer measured by loupe are shown in Table 1 for the bottom, corner, and lower side areas of the crucible, respectively. Test crucibles G and H were made according to prior art methods. Specifically, test crucible G is the same as test crucible A, except that test crucible G was not roughened in any portion. Test crucible G did not complete a 120 hour test.

Although test crucible H finished the 120 hour test, successful completion of the test required fine tuning the CZ process parameters. As illustrated in test crucibles A-F, crucibles made according to embodiments of the invention, i.e., those that include some amount of surface roughness of their doped inner layer, were successful despite not requiring the fine-tuning details of crucible H.

Test crucibles A, B, C, D, and E included roughened surfaces on the corner wall and lower side wall, while test crucible D included roughened surfaces on all of the doped inner-surface.

FIGS. 6 and 7 illustrate a problem that may occur if an inner layer is doped at a relatively high concentration (>100 ppm) in a relatively thick layer (>0.5 mm). As mentioned above, the doped inner-layer is crystallized during the CZ process. If the Ba concentration and thickness of the doped layer is optimized, such as set forth above, the crystallized layer is formed on the normal substrate, as illustrated in FIG. 6. FIG. 6 illustrates a section of a crucible 600 that has a doped inner-layer 602 made according to the preferred method described above. A crystallized surface 610 on the doped inner-layer 602 that is formed during a CZ process is uniform. Instead, if the doped inner-layer is too thick, or if the temperature during the CZ process is extremely hot, bubbles may form in the crucible. This is illustrated in FIG. 7, where bubbles 720 formed in a corner of a crucible 700 that included either a doped inner-layer 702 that was too thick or was heated too much. Note that a crystallized surface is non-uniform in the surface 730 above the bubbles 720.

It is thought that the bubbles 720 formed under the doped inner-layer 710, and particularly in the area 730 above the bubbles 720 are the cause of “melt-penetration,” which is penetration of silicon through holes in the crystallized layer 710. There are two reasons why this melt penetration normally happens in the corner. One reason is that the doped layer is thicker in the corner. The other reason is that the corner region is the hottest region of the crucible during the CZ process.

To be successful at creating an ideal doped inner-layer, factors of the doped inner-layer should be controlled, especially at the corners, such as controlled doping concentrations, controlled thickness, and surface roughening, as described above. This combination will allow a uniform crystallization layer to be formed as illustrated in FIG. 6.

Having described and illustrated the principles of the invention with reference to illustrated embodiments, it will be recognized that the illustrated embodiments may be modified in arrangement and detail without departing from such principles, and may be combined in any desired manner. And although the foregoing discussion has focused on particular embodiments, other configurations are contemplated.

In particular, even though expressions such as “according to an embodiment of the invention” or the like are used herein, these phrases are meant to generally reference embodiment possibilities, and are not intended to limit the invention to particular embodiment configurations. As used herein, these terms may reference the same or different embodiments that are combinable into other embodiments.

Consequently, in view of the wide variety of permutations to the embodiments described herein, this detailed description and accompanying material is intended to be illustrative only, and should not be taken as limiting the scope of the invention. What is claimed as the invention, therefore, is all such modifications as may come within the scope and spirit of the following claims and equivalents thereto.

What is claimed is:

1. A silica crucible, comprising:
a first body portion having substantially straight walls; and
a second body portion having substantially curved walls, the first and second body portions integrally coupled to one another, at least a portion of an inner surface of the curved walls comprising a barium-doped layer of silica having a surface roughness greater than 0.07 micrometers and less than 10 micrometers.

2. The silica crucible according to claim 1, in which the first body portion comprises an upper side wall and a lower side wall, and in which the barium-doped layer is disposed on an inner surface of the lower side wall but not the upper side wall.

3. The silica crucible according to claim 1, in which the second body portion includes a corner wall and a bottom wall, and in which the barium-doped layer of silica covering the corner wall has a roughened surface, and in which the barium-doped layer of silica covering the bottom wall has a relatively smooth surface.

4. The silica crucible according to claim 1, in which the first body portion comprises an upper side wall and a lower side wall, in which the second body portion includes a corner wall and a bottom wall, and in which the upper side wall and the bottom wall are relatively smooth.

5. The silica crucible according to claim 1, in which the barium-doped layer of silica is thicker than 0.2 mm.

6. The silica crucible according to claim 4, in which the barium-doped layer of silica has a thickness of up to 0.8 mm.

7. The silica crucible according to claim 1, in which the barium-doped layer of silica has a varying thickness.

8. The silica crucible according to claim 7, in which the barium-doped layer of silica has a thickness that is thicker at the corner wall than at the bottom wall.

9. The silica crucible according to claim 7, in which the barium-doped layer of silica has a thickness that is thicker at the corner wall than at the side wall.

10. The silica crucible according to claim 7, in which the barium-doped layer of silica has a thickness that is thicker at the bottom wall than at the side wall.

11. The silica crucible according to claim 1, in which the surface roughness is greater than 0.15 micrometers.

12. The silica crucible according to claim 11, in which the surface roughness is less than 5 micrometers.

13. The silica crucible according to claim 1, in which the barium-doped layer of silica has a barium concentration between approximately 30-300 ppm.

14. The silica crucible according to claim 13, in which the barium-doped layer of silica has a barium concentration between approximately 80-200 ppm.

15. The silica crucible according to claim 13, in which the barium-doped layer of silica has a barium concentration between approximately 100-150 ppm.

16. A silica crucible having a bottom wall, a curved wall, and a straight wall, the crucible comprising:
an inner surface of the crucible formed comprising a barium-doped layer of silica; and
at least the inner surface of the curved wall having a surface roughness greater than 0.07 micrometers and less than 10 micrometers.

17. The silica crucible of claim 16, where the entire barium-doped inner surface has a surface roughness greater than 0.07 micrometers and less than 10 micrometers.

18. A method of making a silica crucible include a first portion having relatively straight side walls and a second portion having relatively curved walls, the first portion coupled to the second portion, the method comprising:
forming a barium-doped layer on an inner surface of at least a portion of the curved walls; and
roughening at least a portion of the barium doped layer.

19. The method according to claim 18, in which the curved walls include a corner wall section and a bottom wall section, and in which roughening the barium doped layer comprises roughening the inner surface of the barium-doped layer at the corner wall section, and not roughening the inner surface of the barium-doped layer at the bottom wall section.

20. The method according to claim 18, in which roughening the barium doped layer comprises sand blasting the barium-doped layer.

21. The method according to claim 20, in which sand blasting the barium-doped layer comprises sand blasting the barium-doped layer using a quartz grain media.

22. The method according to claim 21 in which the quartz grain media has approximately the same purity as the silica comprising the silica crucible.

23. The method according to claim 18, in which roughening the barium doped layer comprises lapping the barium-doped layer.

24. The method according to claim 23, in which lapping the inner surface comprises lapping the inner surface using quartz sand.

25. The method according to claim 18, in which roughening the barium doped layer occurs before the crucible is removed from its forming mold.

26. The method according to claim 18, in which roughening the barium doped layer occurs after the crucible is removed from its forming mold.

27. A method of forming a silicon ingot comprising:
placing solid silicon in a silica crucible that includes at least a portion of an inner surface comprising a barium-doped layer of silica having a surface roughness greater than approximately 0.07 micrometers and less than approximately 10 micrometers;
melting the silicon in the crucible; and
drawing the silicon ingot from the crucible.

28. The method of forming a silicon ingot according to claim 27, further comprising:
placing additional solid silicon in the crucible as the silicon ingot is being drawn;
melting the additional solid silicon; and
drawing more of the silicon ingot from the crucible.

29. The method of forming a silicon ingot according to claim 27, further comprising:
placing additional solid silicon in the crucible as the silicon ingot is being drawn;
melting the additional solid silicon; and
drawing a second silicon ingot from the crucible.
